(19) United States
(12) Patent Application Publication
(10) Pub. No.: US 2022/0080552 A1
(43) Pub. Date: Mar. 17, 2022

(54) POLISHING LIQUID SUPPLY DEVICE

(71) Applicant: DISCO CORPORATION, Tokyo (JP)

(72) Inventors: Hideji HORITA, Tokyo (JP); Tomohiro KANEKO, Tokyo (JP); Yuya TANAKA, Tokyo (JP)

(21) Appl. No.: 17/408,697

(22) Filed: Aug. 23, 2021

(30) Foreign Application Priority Data
Sep. 16, 2020 (JP) 2020-155606

(51) Int. Cl. B24B 57/02

(52) U.S. Cl. CPC B24B 57/02

(57) ABSTRACT

Provided is a polishing liquid supply device capable of selectively supplying a plurality of different polishing liquids to a vessel for storing the polishing liquid used in a polishing apparatus. The polishing liquid supply device includes a plurality of ejection nozzles provided according to the plurality of different polishing liquids, a sensor that detects a position corresponding to one of the plurality of ejection nozzles at which a supplied port of the vessel is disposed, a storage device that stores information concerning the polishing liquid selected from the plurality of polishing liquids, and a processing device that performs a control to eject the polishing liquid from the ejection nozzle corresponding to the polishing liquid indicated by the information stored in the storage device.

### BACKGROUND OF THE INVENTION

### Field of the Invention

The present invention relates to a polishing liquid supply device capable of supplying a plurality of different polishing liquids.

### Description of the Related Art

In order to enhance flatness of a wafer sliced from an ingot including a semiconductor or the like, a polishing technology represented by chemical mechanical polishing has been used (see, for example, Japanese Patent Laid-open No. 2012-253259). On a front surface of the wafer enhanced in flatness by the polishing, devices such as semiconductor integrated circuits are formed later.

In the chemical mechanical polishing, the wafer and a polishing pad are both rotated, and the polishing pad is pressed against the front surface of the wafer while supplying a polishing liquid to the front surface of the wafer. The polishing liquid is generated, for example, by mixing a chemical liquid and water, and the result of polishing is varied when the kind, concentration and the like of the chemical liquid contained in the polishing liquid is varied. Therefore, in the chemical mechanical polishing, a management to prevent mistake of the polishing liquid is important.

### SUMMARY OF THE INVENTION

For the above-mentioned reason, generally, for generation of the polishing liquids, a dedicated polishing liquid generating device corresponding to each polishing liquid is used. However, for example, in the case where a plurality of different polishing liquids are used in one plant, it is necessary to install a plurality of polishing liquid generating devices corresponding to each polishing liquid in the plant, so that there has been room for improvement as to cost and space.

Accordingly, it is an object of the present invention to provide a polishing liquid supply device capable of supplying, without mistake, a plurality of different polishing liquids into a vessel corresponding to each polishing liquid.

In accordance with an aspect of the present invention, there is provided a polishing liquid supply device capable of selectively supplying a plurality of different polishing liquid to a vessel for storing the polishing liquid used in a polishing apparatus. The polishing liquid supply device includes a plurality of ejection nozzles provided according to the plurality of different polishing liquids, a sensor that detects a position corresponding to one of the plurality of ejection nozzles at which a supplied port of the vessel is disposed, a storage device that stores information concerning the polishing liquid selected from the plurality of polishing liquids, and a processing device that performs a control to eject the polishing liquid from the ejection nozzle corresponding to the polishing liquid indicated by the information stored in the storage device in a case where the ejection nozzle corresponding to the polishing liquid indicated by the information stored in the storage device and a position of the supplied port of the vessel detected by the sensor correspond to each other.

Preferably, the polishing liquid supply device further includes a fitting member that is fitted in a recess provided at a bottom portion of the vessel and limits the position where the supplied port of the vessel is disposed.

The polishing liquid supply device according to the described aspect of the present invention ejects the polishing liquid from the ejection nozzle only in the case where the ejection nozzle corresponding to the polishing liquid selected from among the plurality of polishing liquids and a position of the supplied port of the vessel detected by the sensor correspond to each other, and, therefore, the plurality of different polishing liquids can be supplied, without mistake, into the vessel corresponding to each polishing liquid.

The above and other objects, features and advantages of the present invention and a manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting a polishing liquid supply device;

FIG. 2 is a front view depicting a structure of the inside of the polishing liquid supply device;

FIG. 3 is a functional block diagram depicting connection relations of a plurality of elements constituting the polishing liquid supply device;

FIG. 4 is a perspective view depicting a vessel;

FIG. 5 is a perspective view depicting the polishing liquid supply device in a state in which a support table is drawn out from a housing;

FIG. 6 is a perspective view of the polishing liquid supply device in a state in which the vessel is mounted on the support table drawn out;

FIG. 7 is a perspective view of the polishing liquid supply device in a state in which the vessel is accommodated in the housing together with the support table;

FIG. 8 is a front view depicting a manner in which a first polishing liquid is supplied from a first polishing liquid generating unit into the vessel;

FIG. 9 is a front view depicting a manner in which a second polishing liquid is supplied from a second polishing liquid generating unit into the vessel; and

FIG. 10 is a perspective view depicting a polishing apparatus that uses the polishing liquid reserved in the vessel.

### DETAILED DESCRIPTION OF THE PREFERRED EMBODIMENT

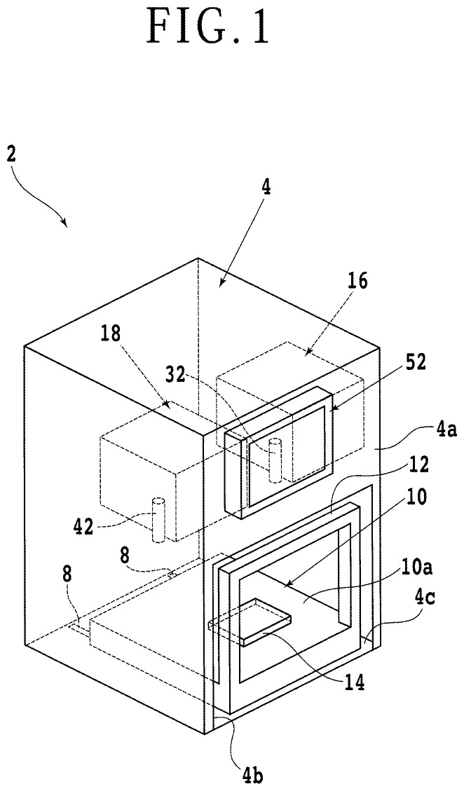

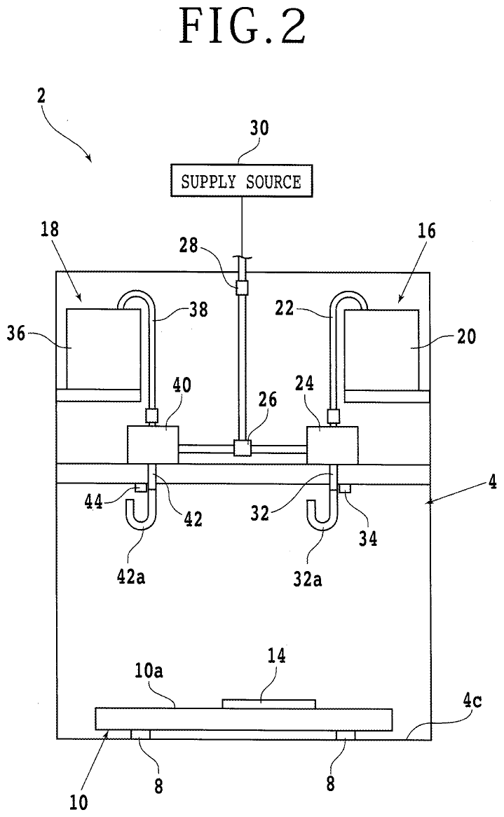

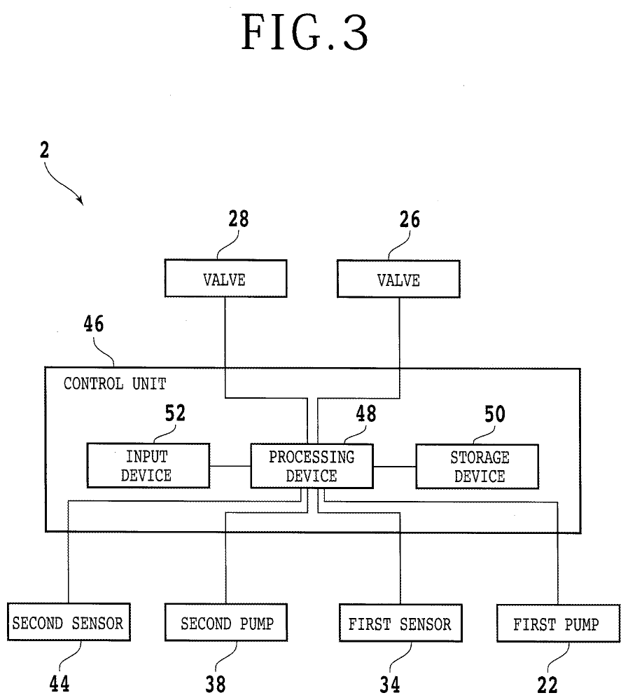

An embodiment of the present invention will be described below referring to the attached drawings. FIG. 1 is a perspective view depicting a polishing liquid supply device 2 according to the present embodiment, FIG. 2 is a front view depicting an inside structure of the polishing liquid supply device 2, and FIG. 3 is a functional block diagram depicting connection relations of a plurality of elements constituting the polishing liquid supply device 2. Note that, in FIGS. 1, 2 and 3, for convenience of explanation, part of the elements is omitted. In addition, in FIG. 2, part of the elements is expressed by a functional block.

As illustrated in FIGS. 1 and 2, the polishing liquid supply device 2 has, for example, a rectangular parallelepiped housing 4 on which to mount various component elements. A front wall 4a of the housing 4 is formed at a lower portion thereof with a rectangular opening 4b connecting the inside and the outside of the housing 4. A pair of guide rails 8 having a predetermined length in a front-back direction are fixed on an upper surface of a bottom wall 4c of the housing 4.

A support table 10 configured to be able to support a vessel for storing a polishing liquid is attached to the pair of guide rails 8 in a manner of being able to be slid forward and backward along the pair of guide rails 8. A handle 12 to be grasped when sliding the support table 10 is provided at an upper portion of a front end of the support table 10.

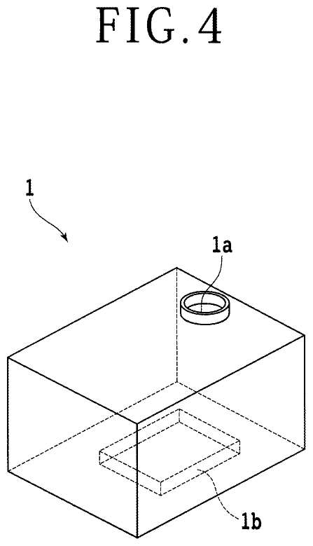

FIG. 4 is a perspective view depicting a vessel 1 for storing a polishing liquid. The vessel 1 is formed, for example, in a hollow shape from a resin such as polyethylene. As depicted in FIG. 4, an upper wall of the vessel 1 is provided with an opening (supplied port) 1a penetrating the upper wall, the polishing liquid is supplied from the exterior of the vessel 1 into the inside space of the vessel 1 and discharged from the inside space of the vessel 1 to the exterior of the vessel through the opening 1a. A bottom wall of the vessel 1 is formed with a recess 1b hollowed upward. The shape of the hollow of the recess 1b is, for example, rectangular parallelepiped.

In a state in which the above-mentioned support table 10 is drawn out to a front side of the housing 4 through the opening 4b, the vessel 1 is mounted on an upper surface 10a of the support table 10. On the upper surface 10a of the support table 10, a protuberant member (fitting member) 14 conforming to the shape of the hollow of the recess 1b of the vessel 1 is disposed. The protuberant member 14 is configured to be able to be disposed at either one of two different positions on the upper surface 10a of the support table 10, and, by fitting in the recess 1b of the vessel 1, limits the position where the opening 1a of the vessel 1 is disposed.

In an upper-side region of the inside of the housing 4, a first polishing liquid generating unit 16 capable of generating and supplying a first polishing liquid and a second polishing liquid generating unit 18 capable of generating and supplying a second polishing liquid are disposed in a manner of being aligned in a left-right direction. As depicted in FIG. 2, the first polishing liquid generating unit 16 includes a first chemical liquid vessel 20 in which a first chemical liquid as a material of the first polishing liquid is reserved.

A first pump 22 is connected to an upper portion of the first chemical liquid vessel 20, and the first chemical liquid reserved in the first chemical liquid vessel 20 is discharged to the exterior of the first chemical liquid vessel 20 by the first pump 22. A first mixing section 24 is connected to the downstream side of the first pump 22. The first chemical liquid discharged from the first chemical liquid vessel 20 by the first pump 22 is supplied to the first mixing section 24.

In addition, a supply source 30 for supplying water (pure water) through a channel selection valve 26, a flow rate control valve 28, and the like is connected to the first mixing section 24. The water supplied from the supply source 30 to the first mixing section 24 through the valve 28 and the valve 26 is mixed with the first chemical liquid in the first mixing section 24. As a result, the first polishing liquid formed by diluting the first chemical liquid with water is generated.

The first mixing section 24 is provided with a first ejection nozzle 32, and the first polishing liquid generated in the first mixing section 24 is supplied into the corresponding vessel 1 through the first ejection nozzle 32. Note that a tip portion 32a of the first ejection nozzle 32 is formed of a flexible resin or the like, and, in a situation where the first ejection nozzle 32 is not used, the tip portion 32a is accommodated in a manner of being wound, as depicted in FIG. 2.

In the vicinity of the first ejection nozzle 32, a first sensor 34 that detects whether or not the opening 1a of the vessel 1 is disposed on the lower side of the first ejection nozzle 32 is disposed. The first sensor 34 is, for example, an optical type sensor that detects an object on a non-contact basis. However, it is to be noted that the kind and the like of the first sensor 34 are not limited. As the first sensor 34, a sensor of an optional system inclusive of a contact type sensor can be used.

The structure of the second polishing liquid generating unit 18 is similar to the structure of the first polishing liquid generating unit 16. In other words, the second polishing liquid generating unit 18 includes a second chemical liquid vessel 36 in which a second chemical liquid as a material of a second polishing liquid is reserved. A second pump 38 is connected to an upper portion of the second chemical liquid vessel 36, and the second chemical liquid reserved in the second chemical liquid vessel 36 is discharged to the exterior of the second chemical liquid vessel 36 by the second pump 38.

A second mixing section 40 is connected to the downstream side of the second pump 38. The second chemical liquid discharged from the second chemical liquid vessel 36 by the second pump 38 is supplied to the second mixing section 40. The supply source 30 is connected also to the second mixing section 40 through the channel selection valve 26, the flow rate control valve 28, and the like. The water supplied from the supply source 30 to the second mixing section 40 through the valve 28 and the valve 26 is mixed with the second chemical liquid in the second mixing section 40. As a result, the second polishing liquid obtained by diluting the second chemical liquid with water is generated.

The second mixing section 40 is provided with a second ejection nozzle 42, and the second polishing liquid generated in the second mixing section 40 is supplied to the corresponding vessel 1 through the second ejection nozzle 42. Note that a tip portion 42a of the second ejection nozzle 42 also is formed, for example, of a flexible resin or the like, and, in a situation where the second ejection nozzle 42 is not used, the tip portion 42a is accommodated in the manner of being wound, as depicted in FIG. 2.

In the vicinity of the second ejection nozzle 42, a second sensor 44 that detects whether or not the opening 1a of the vessel 1 is disposed on the lower side of the second ejection nozzle 42. The second sensor 44 is, for example, an optical type sensor that detects an object on a non-contact basis. However, it is to be noted that the kind and the like of the second sensor 44 are not limited. As the second sensor 44, a sensor of an optional system inclusive of a contact type sensor can be used.

The above-mentioned two positions where to dispose the protuberant member 14 are determined such that the opening 1a of the vessel 1 can be disposed directly below the first ejection nozzle 32 or directly below the second ejection nozzle 42 in the case where the vessel 1 is mounted on the upper surface 10a of the support table 10 such that the protuberant member 14 is fitted in the recess 1b and the vessel 1 is accommodated in the inside of the housing 4. For example, the protuberant member 14 is attached to the support table 10 such as to be manually or automatically moved between the above-mentioned two positions along the upper surface 10a of the support table 10.

As illustrated in FIG. 3, the elements such as the first pump 22, the channel selection valve 26, the flow rate control valve 28, the first sensor 34, the second pump 38, and the second sensor 44 are connected with a control unit 46 capable of controlling them. The control unit 46 includes, for example, a computer including a processing device 48, a storage device 50, and an input device 52.

The processing device 48 is representatively a central processing unit (CPU) and performs various kinds of processing necessary for controlling the above-mentioned elements. The storage device 50 includes, for example, a main storage device such as a dynamic random access memory (DRAM), and an auxiliary storage device such as a hard disc drive and a flash memory. The input device 52 in the present embodiment is a touch panel (FIG. 1) fixed to the front wall 4a of the housing 4, and functions also as an output device (display device). Note that a keyboard, a mouse, and the like may be used as the input device 52.

The function of the control unit 46 is realized, for example, by an operation of the processing device 48 according to a software stored in the storage device 50. However, it is to be noted that the function of the control unit 46 may be realized only by a hardware. The function of the control unit 46 will be described in detail later.

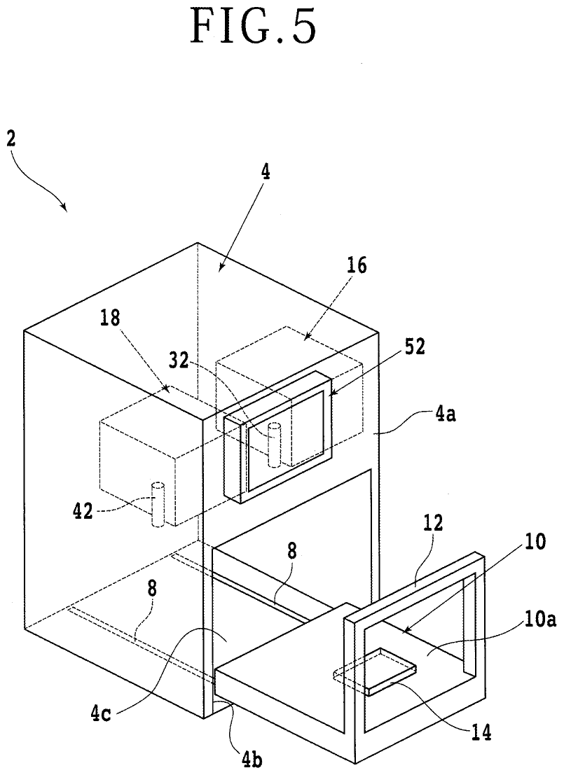

When the first polishing liquid is supplied from the polishing liquid supply device 2 configured as above into the vessel 1, for example, an operator grasps the above-mentioned handle 12 and draws out the support table 10 to the front side of the housing 4. FIG. 5 is a perspective view depicting the polishing liquid supply device 2 in a state in which the support table 10 is drawn out from the housing 4.

After the support table 10 is drawn out from the housing 4, the protuberant member 14 is positioned at a first position corresponding to the first polishing liquid desired to be supplied. Here, the first position is a position at which the opening 1a of the vessel 1 can be disposed directly below the first ejection nozzle 32, in the case where the vessel 1 is mounted on the upper surface 10a of the support table 10 such that the protuberant member 14 is fitted in the recess 1b and the vessel 1 is accommodated in the inside of the housing 4.

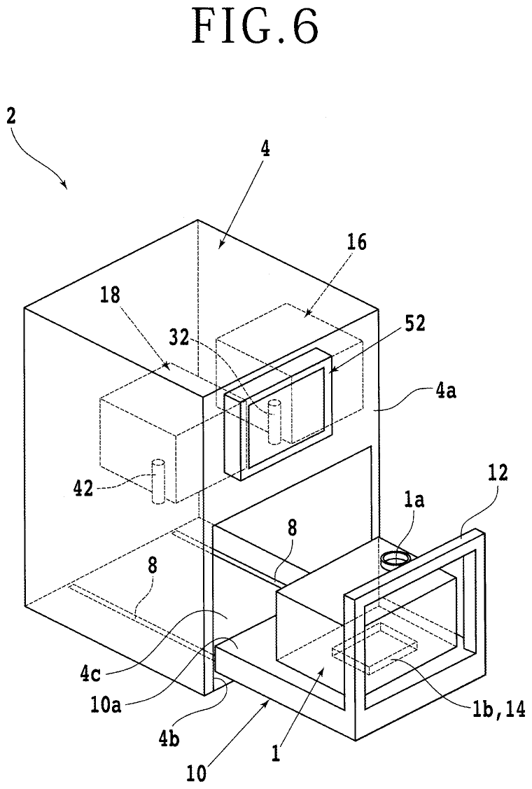

After the protuberant member 14 is positioned at the first position, the vessel 1 is mounted on the upper surface 10a of the support table 10. FIG. 6 is a perspective view depicting the polishing liquid supply device 2 in a state in which the vessel 1 is mounted on the support table 10 drawn out. For example, the vessel 1 is mounted on the upper surface 10a of the support table 10 while aligning the direction of the vessel 1 such that the opening 1a of the vessel 1 is disposed directly below the first ejection nozzle 32 when the support table 10 is slid and accommodated in the inside of the housing 4.

Note that the recess 1b and the protuberant member 14 are formed in a rectangular parallelepiped shape in rotational symmetry, so that the protuberant member 14 can be fitted in the recess 1b, even where the direction of the vessel 1 is opposite in the left-right direction (in a state in which the vessel 1 is rotated around a vertical axis). On the other hand, the polishing liquid supply device 2 and the vessel 1 in the present embodiment are configured such that the opening 1a of the vessel 1 is not disposed directly below the first ejection nozzle 32 or directly below the second ejection nozzle 42 in the case where the direction and/or position of the vessel 1 is improper.

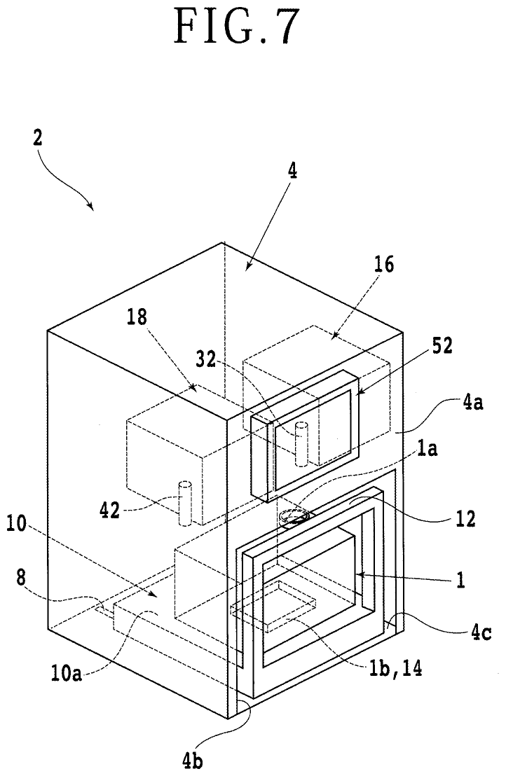

After the vessel 1 is mounted on the upper surface 10a of the support table 10, the support table 10 is slid and accommodated in the inside of the housing 4. FIG. 7 is a perspective view depicting the polishing liquid supply device 2 in a state in which the vessel 1 is accommodated in the housing 4 together with the support table 10. As depicted in FIG. 7, when the vessel 1 is accommodated in the inside of the housing 4, the opening 1a of the vessel 1 is disposed directly below the first ejection nozzle 32.

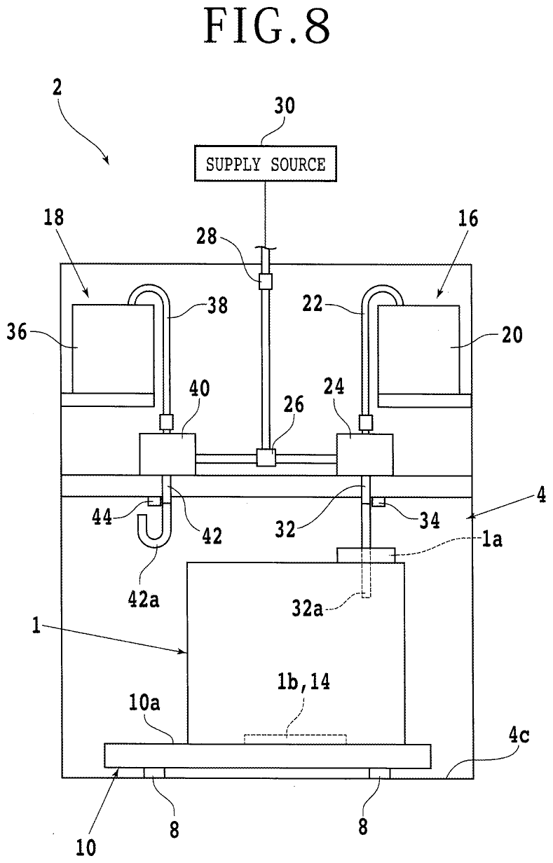

Note that, after the opening 1a of the vessel 1 is disposed directly below the first ejection nozzle 32, the tip portion 32a of the first ejection nozzle 32 that has been accommodated in the manner of being wound is drawn out downward, and is inserted into the opening 1a. FIG. 8 is a front view depicting a manner in which the first polishing liquid is supplied from the first polishing liquid generating unit 16 into the vessel 1.

After the vessel 1 is accommodated into the inside of the housing 4, for example, the operator inputs the information concerning the first polishing liquid desired to be supplied, to the processing device 48 through the input device 52. When the information concerning the first polishing liquid is inputted to the processing device 48 through the input device 52, the processing device 48 stores the information in the storage device 50.

Thereafter, the processing device 48 confirms that the object of supply is the first polishing liquid, by referring to the information stored in the storage device 50, and determines whether or not the opening 1a of the vessel 1 is disposed on the lower side of the first ejection nozzle 32 for supplying the first polishing liquid indicated by this information.

Specifically, by the first sensor 34 and the second sensor 44, it is detected whether or not the opening 1a of the vessel 1 is disposed at either position of the first ejection nozzle 32 and the second ejection nozzle 42. Then, it is determined whether or not the position of the first ejection nozzle 32 for supplying the first polishing liquid and the position of the opening 1a of the vessel 1 detected correspond to each other.

In the case where the opening 1a is not detected by the first sensor 34, for example, in the case where the opening 1a is detected by the second sensor 44, or in the case where the opening 1a is not detected by either of the first sensor 34 and the second sensor 44, the processing device 48 does not start an operation concerning the supply of the first polishing liquid (and an operation concerning the supply of the second polishing liquid). Note that it is desirable that the processing device 48 report the situation to the operator by the input device 52 functioning also as the output device (display device), or the like. As a result, a swift correspondence by the operator is possible.

In the case where the opening 1a is detected by the first sensor 34, the processing device 48 operates the first pump 22 for supplying the first chemical liquid necessary for generating the first polishing liquid, to supply the first chemical liquid to the first mixing section 24. In addition, the processing device 48 controls the flow rate control valve 28 according to concentration and the like of the first chemical liquid necessary for generating the first polishing liquid, and controls the channel selection valve 26 such that water flows to the first mixing section 24, thereby to supply the first mixing section 24 with the water in an amount necessary for generating the first polishing liquid.

The first mixing section 24 mixes the first chemical liquid and the water supplied thereto, to generate the first polishing liquid. The first polishing liquid thus generated is ejected through the first ejection nozzle 32. As above-mentioned, the position of the first ejection nozzle 32 and the position of the opening 1a of the vessel 1 correspond to each other, and the opening 1a of the vessel 1 is disposed on the lower side of the first ejection nozzle 32. Therefore, the first polishing liquid ejected through the first ejection nozzle 32 is supplied into the inside of the vessel 1 through the opening 1a.

The procedure, the operation, and the like when supplying the second polishing liquid from the polishing liquid supply device 2 to the vessel 1 are similar. Specifically, the operator draws out the support table 10 from the housing 4, positions the protuberant member 14 at the second position corresponding to the second polishing liquid desired to the supplied, mounts the vessel 1 on the upper surface 10a of the support table 10 such that the protuberant member 14 is fitted into the recess 1b, and slides the support table 10 to accommodate the support table 10 into the housing 4.

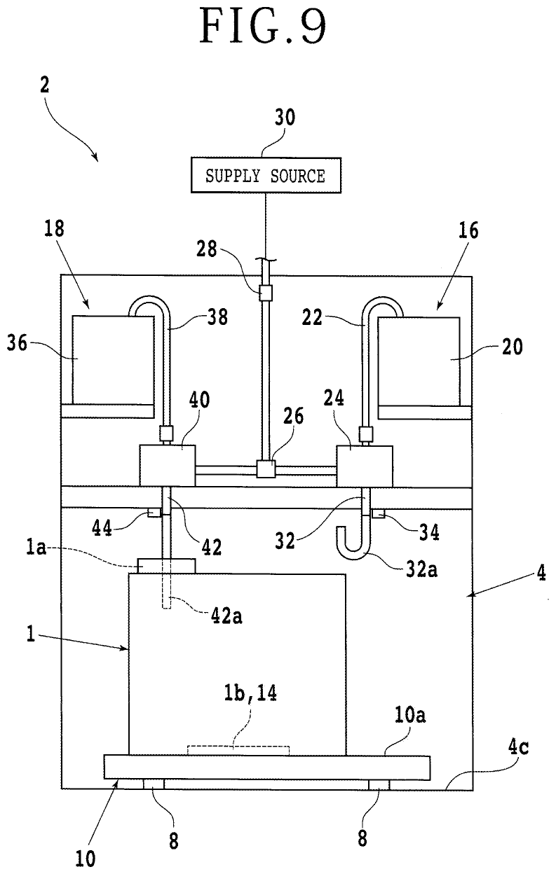

Note that, after the opening 1a of the vessel 1 is disposed directly below the second ejection nozzle 42, the tip portion 42a of the second ejection nozzle 42 having been accommodated in the state of being wound is drawn out downward, and is inserted into the opening 1a. FIG. 9 is a front view depicting a manner in which the second polishing liquid is supplied from the second polishing liquid generating unit 18 into the vessel 1.

Thereafter, the operator input the information concerning the second polishing liquid desired to be supplied, to the processing device 48 through the input device 52. When the information concerning the second polishing liquid is inputted to the processing device 48, the processing device 48 stores the information into the storage device 50. Thereafter, the processing device 48 confirms that the object of supply is the second polishing liquid, by referring to the information stored in the storage device 50, and determines whether or not the opening 1a of the vessel 1 is disposed on the lower side of the second ejection nozzle 42 for supplying the second polishing liquid indicated by the information.

In other words, by the first sensor 34 and the second sensor 44, it is determined whether or not the opening 1a of the vessel 1 is disposed at a position corresponding to either of the first ejection nozzle 32 and the second ejection nozzle 42. Then, it is determined whether or not the position of the second ejection nozzle 42 for supplying the second polishing liquid and the position of the opening 1a of the vessel 1 detected correspond to each other.

In the case where the opening 1a is not detected by the second sensor 44, for example, in the case where the opening 1a is detected by the first sensor 34, or in the case where the opening 1a is not detected by either of the first sensor 34 and the second sensor 44, the processing device 48 does not start an operation concerning the supply of the second polishing liquid (and an operation concerning the supply of the first polishing liquid). Note that, in this case, also, it is desirable that the processing device 48 reports this situation to the operator by the input device 52 functioning also as an output device (display device), or the like.

In the case where the opening 1a is detected by the second sensor 44, the processing device 48 operates the second pump 38 for supplying the second chemical liquid necessary for generating the second polishing liquid, to supply the second chemical liquid to the second mixing section 40. In addition, the processing device 48 controls the flow rate control valve 28 according to the concentration and the like of the second chemical liquid necessary for generating the second polishing liquid, and controls the channel selection valve 26 such that water flows to the second mixing section 40, to supply the second mixing section 40 with wafer in an amount necessary for generating the second polishing liquid.

The second mixing section 40 mixes the second chemical liquid and the water supplied thereto, to generate the second polishing liquid. The second polishing liquid thus generated is ejected through the second ejection nozzle 42. As above-mentioned, the position of the second ejection nozzle 42 and the position of the opening 1a of the vessel 1 correspond to each other, and the opening 1a of the vessel 1 is disposed on the lower side of the second ejection nozzle 42. Therefore, the second polishing liquid ejected through the second ejection nozzle 42 is supplied into the inside of the vessel 1 through the opening 1a.

In such a way, since the polishing liquid supply device 2 according to the present embodiment ejects the polishing liquid through the ejection nozzle only in the case where the ejection nozzle (the first ejection nozzle 32 and the second ejection nozzle 42) corresponding to the polishing liquid selected from among the plurality of polishing liquid (the first polishing liquid and the second polishing liquid) and the position of the opening (supplied port) 1a of the vessel 1 detected by the sensor (the first sensor 34 and the second sensor 44) correspond to each other, and, therefore, is capable of supplying, without mistake, the plurality of different polishing liquids to the vessel 1 corresponding to each polishing liquid.

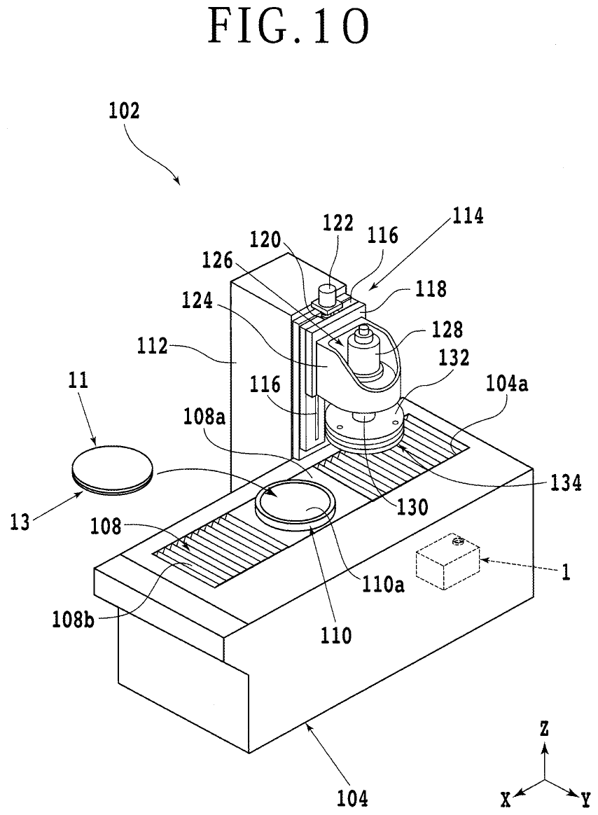

The vessel 1 after supplied with the polishing liquid in the above-mentioned manner is conveyed into the polishing apparatus and used. FIG. 10 is a perspective view depicting a polishing apparatus 102 that uses the polishing liquid reserved in the vessel 1. Note that an X-axis direction (left-right direction), a Y-axis direction (front-back direction), and a Z-axis direction (vertical direction) used in the following description are orthogonal to one another.

As illustrated in FIG. 10, the polishing apparatus 102 includes a base 104 on which each element is mounted. An upper surface of the base 104 is formed with an opening 104a which is elongated in the X-axis direction. A ball screw type X-axis moving mechanism 108, a first cover 108a covering the upper side of the X-axis moving mechanism 108, and a bellows-like second cover 108b connected to the first cover 108a are disposed in the opening 104a. The X-axis moving mechanism 108 includes an X-axis moving table (not illustrated) covered by the first cover 108a, and moves the X-axis moving table in the X-axis direction.

A chuck table 110 for holding a plate-shaped workpiece 11 is provided on the upper side of the X-axis moving table. The workpiece 11 is, for example, a disk-shaped wafer including a semiconductor such as silicon (Si), and, for example, a protective member 13 including a resin or the like is attached to one surface thereof.

Note that, while the disk-shaped wafer including a semiconductor such as silicon is used as the workpiece 11 in the present embodiment, a material, a shape, a structure, a size, and the like of the workpiece 11 are not limited. For example, a substrate including a material such as other semiconductors, ceramics, resins, and metals can also be used as the workpiece 11. In addition, the workpiece 11 may be formed with devices such as an integrated circuit (IC).

Part of an upper surface of the chuck table 110 is a holding surface 110a for holding the workpiece 11. The holding surface 110a is formed to be porous, for example, by use of a ceramic or the like, and is connected to a suction source (not illustrated) through a suction passage (not illustrated) and the like formed in the inside of the chuck table 110.

The workpiece 11 (protective member 13) is mounted on the holding surface 110a, and a negative pressure of the suction source is made to act thereon, whereby the workpiece 11 can be suction held by the chuck table 110. The chuck table 110 is connected to a rotational drive source (not illustrated) such as a motor, and is rotated around a rotational axis which is substantially parallel to the Z-axis direction. In addition, the chuck table 110 is moved in the X-axis direction together with the X-axis moving table by the above-mentioned X-axis moving mechanism 108.

A columnar support structure 112 is provided on the rear side of the base 104. A Z-axis moving mechanism 114 is provided on a front side of the support structure 112. The Z-axis moving mechanism 114 includes a pair of Z-axis guide rails 116 substantially parallel to the Z-axis direction, and a Z-axis moving plate 118 is attached to the Z-axis guide rails 116 in a slidable manner.

A nut (not illustrated) constituting the ball screw is fixed to the rear side (back side) of the Z-axis moving plate 118, and a screw shaft 120 substantially parallel to the Z-axis guide rails 116 is connected to the nut in a rotatable manner. A Z-axis pulse motor 122 is connected to one end portion of the screw shaft 120. With the screw shaft 120 rotated by the Z-axis pulse motor 122, the Z-axis moving plate 118 is moved in the Z-axis direction along the Z-axis guide rails 116.

A support tool 124 is provided on the front side of the Z-axis moving plate 118. A polishing unit 126 for polishing the workpiece 11 is supported on the support tool 124. The polishing unit 126 includes a spindle housing 128 fixed to the support tool 124. A spindle 130 serving as a rotary shaft is accommodated in the spindle housing 128 in a rotatable manner.

A lower end portion of the spindle 130 is exposed to the exterior through a lower end portion of the spindle housing 128. A disk-shaped wheel mount 132 is provided at the lower end portion of the spindle 130. A disk-shaped polishing pad 134 configured to be substantially equal in diameter to the wheel mount 132 is mounted to a lower surface of the wheel mount 132. Further, a rotational drive source (not illustrated) such as a motor is connected to the upper end side of the spindle 130.

An accommodation chamber (not illustrated) capable of accommodating the above-mentioned vessel 1 is provided inside the base 104. For example, a pump is connected to the opening 1a of the vessel 1, in a state in which the vessel 1 is accommodated in the accommodation chamber. With this pump operated, the polishing liquid can be supplied to the workpiece 11 on the chuck table 110, the polishing pad 134, and the like.

Note that the present invention is not limited to the description of the above-mentioned embodiment but can be carried out with various modifications. For example, while a mode of directly detecting the position of the opening (supplied port) 1a of the vessel 1 by use of the first sensor 34 and the second sensor 44 has been exemplified as an example in the above embodiment, the position of the opening 1a may be indirectly detected by detecting the position, the direction, and the like of the vessel 1 by use of the first sensor 34 and the second sensor 44.

In addition, while the polishing liquid supply device 2 capable of selectively supplying the two different polishing liquids has been exemplified as an example in the above embodiment, the polishing liquid supply device of the present invention may be configured to be able to selectively supply three or more different polishing liquids. In that case, a polishing liquid generating unit or units equivalent to the first polishing liquid generating unit 16 and the second polishing liquid generating unit 18 are disposed according to the number of the polishing liquids. In addition, in this case, the protuberant member 14 is configured such as to be able to be disposed at either of a plurality of different positions according to the number of the polishing liquids.

Besides, while the polishing liquid supply device 2 that selectively supplies the two polishing liquids (the first polishing liquid and the second polishing liquid) generated respectively by use of two kinds of chemical liquids (the first chemical liquid and the second chemical liquid) has been exemplified as an example in the above embodiment, the polishing liquid supply device of the present invention may be configured to be able to selectively supply a plurality of polishing liquids (a plurality of polishing liquids different in the dilution ratio of the chemical liquid) generated by use of one kind of chemical liquid.

In addition, the polishing liquid supply device of the present invention may include a function of automatically finely adjusting the supply amounts of the chemical liquids and water according to the temperatures of the chemical liquids, the water, the environment, and the like. In this case, for example, the polishing liquid supply device include temperature sensors for measuring the temperature of the chemical liquid (the first chemical liquid or the second chemical liquid) reserved in the chemical liquid vessel (the first chemical liquid vessel 20 or the second chemical liquid vessel 36), the temperature of the water supplied from the supply source 30, and the like, and the control unit 46 is configured to be able to adjust the supply amounts of the chemicals and the water according to the information concerning the temperatures obtained by measurement. As a result, the polishing liquids having desired values of chemical liquid concentration can be supplied, without being influenced by variations in the temperatures of the chemical liquids and the water.

Besides, while the polishing liquid supply device 2 having the function of generating and supplying the polishing liquids has been exemplified as an example in the above embodiment, the polishing liquid supply device of the present invention may not have the function of generating the polishing liquids. In other words, it is sufficient that the polishing liquid supply device of the present invention has at least the function of selectively supplying a plurality of polishing liquids. For example, the polishing liquid supply device of the present invention may be configured to be able to selectively supply a plurality of polishing liquids preliminarily generated.

In addition, while the information concerning the polishing liquid (the first polishing liquid or the second polishing liquid) desired to be supplied is inputted to the processing device 48 through the input device 52 after the vessel 1 is accommodated into the inside of the housing 4 in the above embodiment, the vessel 1 may be accommodated into the inside of the housing 4 after the information is inputted to the processing device 48.

In addition, the structures, the methods, and the like according to the above embodiment and modifications may be modified, as required, insofar as the modifications do not depart from the range of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A polishing liquid supply device capable of selectively supplying a plurality of different polishing liquid to a vessel for storing the polishing liquid used in a polishing apparatus, the polishing liquid supply device comprising:
a plurality of ejection nozzles provided according to the plurality of different polishing liquids;
a sensor that detects a position corresponding to one of the plurality of ejection nozzles at which a supplied port of the vessel is disposed;
a storage device that stores information concerning the polishing liquid selected from the plurality of polishing liquids; and
a processing device that performs a control to eject the polishing liquid from the ejection nozzle corresponding to the polishing liquid indicated by the information stored in the storage device in a case where the ejection nozzle corresponding to the polishing liquid indicated by the information stored in the storage device and a position of the supplied port of the vessel detected by the sensor correspond to each other.

2. The polishing liquid supply device according to claim 1, further comprising:
a fitting member that is fitted in a recess provided at a bottom portion of the vessel and limits the position where the supplied port of the vessel is disposed.
